(19) United States
(12) Patent Application Publication
(10) Pub. No.: US 2026/0196387 A1
(43) Pub. Date: Jul. 9, 2026

(54) SUPERCONDUCTING FLEXIBLE INTERCONNECT

(71) Applicant: All Flex Solutions, Inc., Minneapolis, MN (US)

(72) Inventors: Gerald Hatz, Minneapolis, MN (US); Michael Madetzke, Minneapolis, MN (US); Derek Rossberg, Minneapolis, MN (US); Tyler Keeler, Minneapolis, MN (US); Dallas Krech, Minneapolis, MN (US); Mustafa Halim, Minneapolis, MN (US); Conner Staack, Minneapolis, MN (US); Sean Baecker, Minneapolis, MN (US)

(73) Assignee: All Flex Solutions, Inc., Minneapolis, MN (US)

(21) Appl. No.: 19/071,336

(22) Filed: Mar. 5, 2025

Related U.S. Application Data
(60) Provisional application No. 63/561,394, filed on Mar. 5, 2024.
(60) Provisional application No. 63/726,027, filed on Nov. 27, 2024.

(51) Int. Cl. H01B 12/02; H05K 1/11; H05K 3/00; H05K 3/14

(52) U.S. Cl. CPC H01B 12/02; H05K 1/11; H05K 3/0017; H05K 3/146

(57) ABSTRACT

A method of fabricating a superconducting flexible interconnect layer to include selecting a superconducting material and applying at least one layer of the superconducting material to a dielectric material. Next the method requires selectively removing a portion of the superconducting material and applying to exposed superconducting and non-superconducting material at least one of a coverlay, a solder mask or a surface finish to prevent oxidation.

### CROSS REFERENCE TO RELATED APPLICATIONS

This application claims priority from U.S. Provisional Application No. 63/561,394 filed on Mar. 5, 2024, as well as U.S. Provisional Application No. 63/726,027, filed Nov. 27, 2024. The contents of these applications are incorporated herein by reference in their entireties.

### FIELD OF THE DISCLOSURE

A flexible metal trace that links different components within a circuit, allowing electrical signals and power to flow with no resistance through the superconducting elements when cooled below a specific low temperature, allowing for the flow of electrical current with limited to no energy loss.

### BACKGROUND

A flexible superconducting interconnect is a type of electrical interconnect that uses superconducting materials to transfer electrical signals while being flexible enough to bend, twist, or conform to different shapes without losing functionality. These interconnects combine the benefits of superconductivity with the ability to maintain flexibility, making them ideal for applications where both high-performance electrical conductivity and the need for adaptability in shape or space are required.

Superconducting materials exhibit limited to no electrical resistance when cooled below a certain temperature (known as the critical temperature). This property enables lossless transmission of electrical signals, meaning little to no energy is dissipated as heat during the flow of current, even at high current densities. This is a major advantage over conventional metallic interconnects, which suffer from energy losses due to resistance.

Unlike traditional superconducting wires or interconnects, which are typically rigid and difficult to handle and install, flexible superconducting interconnects are designed to maintain their superconducting properties while also being able to bend or conform to curved or irregular surfaces. This flexibility is achieved using special materials, often thin films or composite materials, that maintain superconductivity even under mechanical deformation

The most significant advantage is the limited to no electrical resistance at low temperatures, leading to energy-efficient signal transmission with no loss of power as heat. Due to the flexibility of the material, these interconnects can be used in compact designs where traditional rigid interconnects would be difficult or impossible to integrate. Superconductors can carry much higher currents than regular conductors without heating up, enabling high-power applications in a small form factor. As these interconnects have no resistance at operating temperatures below the critical temperature, they generate no heat, which can be crucial in delicate electronic or medical devices

The process of making superconducting materials flexible and ensuring their superconducting properties under stress is a significant engineering challenge. Many superconducting materials are brittle and can lose their superconducting properties if deformed beyond a certain limit. The production of flexible superconducting interconnects, particularly at scale, can be expensive, especially due to the complex fabrication processes involved.

A flexible superconducting interconnect is a highly promising technology for applications that demand both flexibility and high-performance electrical conductivity. While they currently face challenges related to cooling and material handling, their potential to revolutionize fields like quantum computing, high-performance electronics, and medical imaging is immense. These interconnects combine the best of superconductivity with the adaptability of flexible electronics, making them a cutting-edge solution for next-generation devices

Superconducting interconnects are used in advanced flexible electronic devices. These interconnects can be used in devices requiring low-loss, high-speed data transmission, especially in systems where the interconnects need to fit within compact or non-traditional geometries. In certain applications, flexible superconducting interconnects can be used in medical devices, such as MRI machines, where superconducting magnets are essential, and the flexibility of the interconnect allows better integration into complex medical device layouts. Superconducting interconnects are also used in quantum computers, where low-loss, high-speed interconnections are essential for maintaining quantum coherence.

### SUMMARY

Disclosed herein is the configuration of a superconducting flexible interconnect fabricated from a superconducting material deposited on at least one of a metal layer, a ceramic layer, or an engineered polymer, wherein the flexible superconducting interconnect includes at least one of a single layer or a multi-layer configuration, the multi-layer configuration comprising at least one via path with an electrically conductive material that is at least one of superconducting or non-superconducting.

Also disclosed herein are various methods for fabricating at least one layer of a superconducting flexible interconnect with a superconducting trace, a via and a non-via hole deposited with either a non-superconducting or a superconducting material. One of the disclosed methods, an additive method, requires first selecting an electrically conductive carrier metal. Next, the method requires applying a masking image to the carrier metal and then depositing a superconducting material upon the carrier metal. The method then requires removing the masking image from the surface of the carrier metal thereby leaving a pattern of the superconducting material on top of the carrier metal.

Following the step of removing the masking image the step of laminating at least one layer of the carrier metal with the superconducting image facing a dielectric material is required. After the lamination, the method requires the etching of at least a portion of the carrier metal to expose the superconducting image laminated to the dielectric material. The previously recited steps are then repeated to form the layers of a multilayer subassembly. These layers are then laminated together to form a multilayer flexible interconnect.

Following the formation of the multilayer flexible interconnect, the step of creating at least one of a via or a component hole to electrically connect the superconducting layers using either non-superconducting or superconducting electrically conductive materials is required. Lastly the step of applying to the exposed superconducting and non-superconducting material one of a coverlay, a solder mask or a surface finish to prevent oxidation.

An alternative, subtractive method, of fabricating at least one layer of a superconducting flexible interconnect with a superconducting trace, via, and non-via holes deposited with superconducting or non-superconducting material, the method requires first selecting a superconducting material and then applying at least one layer of the superconducting material to a dielectric material.

Following the applying of a layer, the next step requires adding a masking material and going through an imaging process and then removing selectively a portion of the superconducting material to create the superconducting traces and pads. Then repeating this process to form the layers of a multilayer subassembly. These layers are laminated together to form a multilayer flexible interconnect. For multilayer and double-sided interconnects, the next step requires creating via and non-via holes to electrically connect the superconducting layers and the application of either superconducting or non-superconducting material to via and non-via holes to form a layer-to-layer electrical connection. Lastly the disclosed method requires applying to exposed superconducting or non-superconducting material at least one of a coverlay, a solder mask or a surface finish to prevent oxidation.

Fabricating a superconducting flexible interconnect with superconducting traces, via, and non-via holes—where some materials are superconducting, and others are non-superconducting—offers a wide range of benefits for various advanced electronic and quantum applications. The combination of flexibility, superconductivity, and carefully engineered dielectric and conductive materials provides a powerful platform for creating high-performance interconnects with specific characteristics tailored to the needs of the application.

It is an object of the disclosed device and method to fabricate superconducting traces that exhibit limited to no electrical resistance when cooled below their critical temperature thereby eliminating power losses due to resistive heating, which is especially beneficial in high-speed and high-precision circuits, including those used in quantum computing, high-frequency signal transmission, or cold operating environments.

It is a further object of the disclosed device and method to fabricate an interconnect with limited to no resistive loss in superconducting materials, such that the interconnect allows for highly efficient transmission lines or power delivery, making them ideal for power-sensitive applications, such as superconducting computers, energy-efficient sensors, and low-power quantum devices.

It is a further object of the disclosed device and method for the superconducting interconnects to carry high-frequency signals with minimal attenuation making them suitable for applications such as high-speed communications, radar systems, and advanced RF (radio frequency) circuits.

It is a further object of the disclosed device and method for the fabrication of the superconducting interconnects to be used to create inductive elements to include superconducting coils with minimal loss, which are important for applications in quantum circuits

It is a further object of the disclosed additive and subtractive methodologies to facilitate the fabrication of the superconducting interconnects.

It is a further object of the disclosed method to produce a superconducting interconnect that is highly scalable particularly for quantum computers. The more qubits that are needed for the system, the more critical it is to reduce the size of the interconnects and using traditional superconducting coaxial cables does not allow quantum computers to reach their full potential due to constraints with capacities of cooling systems.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 illustrates a longitudinal extending cross-sectional view a flexible superconducting interconnect;

FIG. 2 illustrates a carrier foil additive method of fabricating a superconducting flexible interconnect;

FIG. 3 illustrates a foil subtractive method of fabricating a superconducting flexible interconnect;

FIG. 4 illustrates a single layer foil method of fabricating a superconducting flexible interconnect; and

FIG. 5 illustrates a carrier foil single layer method of fabricating a superconducting flexible interconnect;

FIG. 6A illustrates a lateral cross-sectional view of a carrier foil with a photo-resist masking applied;

FIG. 6B illustrates the carrier foil with unwanted photoresist masking removed;

FIG. 6C illustrates the carrier foil with superconducting material added;

FIG. 6D illustrates the carrier foil stripped of photoresist leaving only the superconducting traces on the carrier;

FIG. 6E illustrates the lamination layer disposed between the spaced apart carrier with superconducting traces;

FIG. 6F illustrates the lamination layer disposed between and adhered to the carrier with superconducting traces;

FIG. 6G illustrates the application of masking material to the carrier with hardened masking material on one side following an imaging process;

FIG. 6H illustrates the development of masking material leaving masking material on one side only;

FIG. 6I illustrates the carrier foil etched on one side removing the photo resist;

FIG. 6J illustrates the repeating of the steps to create a top layer and the lamination of the top cap to the rest of the circuit;

FIG. 6K illustrates the carrier foil laminated between a top and a bottom cap;

FIG. 6L illustrates the clean barrel of the drilled or lasered via holes;

FIG. 6M illustrates masking material applied and imaged;

FIG. 6N illustrates the masking material being developed to remove unwanted masking;

FIG. 6O illustrates the application of superconductive or non-superconductive material to the via holes;

FIG. 6P illustrates the masking material being removed;

FIG. 6Q illustrates the application of a masking material, imaging, removing/developing a portion of the masking;

FIG. 6R illustrates the etching of a portion of the carrier;

FIG. 6S illustrates the removal of the masking material;

FIG. 6T illustrates a coverlay, soldermask or surface finish being applied to the circuit;

FIG. 6U which details the etching and removal of either all or a portion of the carrier;

FIG. 6 V illustrates the clean barrel of the drilled or lasered via holes;

FIG. 6W illustrates the applied masking material that is imaged;

FIG. 6X illustrates the development of the masking material by selectively exposing the carrier and/or the superconducting layer;

FIG. 6Y illustrates the application of either superconductive or non-superconductive material to the via holes;

FIG. 6Z illustrates the removal of the masking material;

FIG. 6ZA illustrates the application of coverlay, soldermask and or surface finish to complete the fabrication of the flexible superconducting interconnect;

FIG. 7A illustrates a lateral cross-sectional view of the application of a superconducting material to the dielectric;

FIG. 7B illustrates the application of the masking material;

FIG. 7C illustrates the imaging process followed by the development process which has removed the unwanted masking material and then selectively removing a portion of the superconductive layer;

FIG. 7D illustrates the superconducting pattern on the carrier after the removal of the masking image;

FIG. 7E illustrates a layer of the superconducting material is laminated to the dielectric;

FIG. 7F illustrates the laminated flexible interconnect;

FIG. 7G illustrates the via holes that have been formed by drilling or lasering;

FIG. 7H illustrates the masking material as applied to the flexible interconnect and then imaged;

FIG. 7I illustrates the development of the masking material leaving openings over the vias and the superconducting or non-superconducting material is applied to the via holes;

FIG. 7J illustrates removal of the masking material;

FIG. 7K illustrates the application of the imaged masking material;

FIG. 7L illustrates the masking material is developed and the masking material in unwanted areas is removed exposing the superconducting material;

FIG. 7M illustrates that selective portions of the superconducting material is removed;

FIG. 7N illustrates the removal of the masking material; and

FIG. 7O illustrates the application of a coverlay, soldermask, and/or a surface finish to the superconducting flexible interconnect thereby completing the alternative path to fabrication.

### DETAILED DESCRIPTION

The following description is of various exemplary embodiments only, and is not intended to limit the scope, applicability, or configuration of the present disclosure in any way. Rather, the following description is intended to provide a convenient illustration for implementing various embodiments including the best mode. As will become apparent, various changes may be made in the function and arrangement of the elements described in these embodiments without departing from the scope of the appended claims.

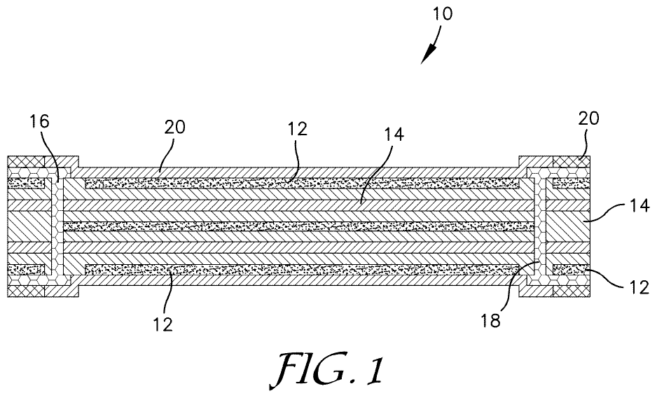

As illustrated at FIG. 1, the disclosed superconducting flexible interconnect 10 includes a superconducting material 12 deposited on at least one of a metal layer, a ceramic layer, or an engineered polymer layer 14. The flexible superconducting interconnect also includes at least one of a single layer or a multi-layer configuration with a multi-layer configuration including at least one via path 16 with an electrically conductive superconducting or a non-superconducting material 18. A coverlay 20 is also illustrated at FIG. 1.

The flexible interconnect may also include a surface finish 20, a stiffener, and may include an assembled or an embedded component. A stiffener in a flexible interconnect circuit is a rigid piece of material added to specific areas of the flexible PCB to provide mechanical support and prevent bending or flexing in delicate regions like connector points, essentially making that section of the circuit more rigid while allowing other parts to remain flexible. A stiffener is used to protect components and ensure proper functionality in high-stress areas. An embedded component in a flexible interconnect circuit refers to a passive electronic component like a resistor, capacitor, or inductor that is directly integrated within the flexible circuit board's substrate, rather than being placed on the surface as a separate component, allowing for smaller size, higher density, and improved signal integrity within the circuit.

The surface finish 20 includes at least one of electroless nickel immersion gold (ENIG), electroless nickel electroless palladium immersion gold (ENEPIG), hot air soldering level (HASL), organic solderability preservative (OSP), hard gold, immersion or electrolytic silver, electroless palladium/immersion gold (EPIG), immersion or electrolytic tin or high phosphorous electroless nickel immersion gold.

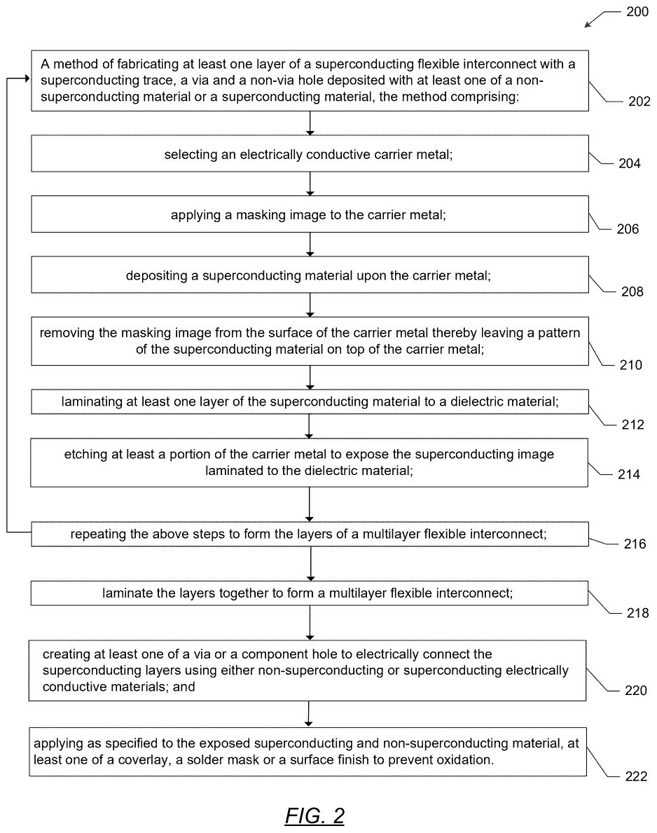

As illustrated at FIG. 2, disclosed is a first method 200 of fabrication of a single layer 102 of a superconducting flexible interconnect 104. This additive method 200 includes a superconducting trace 106, a via 108 and a non-via hole 110 deposited with at least one of a non-superconducting material or a superconducting material 112. The method 202 requires the step of initially selecting 204 an electrically conductive carrier metal 114.

Next, a masking image, the application of which is well understood in the art, is applied 206 to the carrier metal 114. A masking image refers to a pattern or mask used during the fabrication process to selectively define the regions where materials should be deposited, etched, or removed on a substrate. The masking image as disclosed herein preferably includes at least one of a dry film, a liquid photoresist or a solder mask. The masking image serves to protect certain areas of the interconnect while allowing for precise manufacturing in other areas.

The benefits of dry film masking, such as Rison® produced by the DuPont™ Corporation, includes thickness control as the dry film process can create thick solder mask layers by laminating multiple layers of film. Dry film, importantly, can be placed and aligned very accurately, is suitable for high-density and fine-line circuit boards and prevents the formation of solder bridges during soldering. Vacuum lamination forces the dry film to adhere to the interconnect and removes bubbles. The layer is then exposed to UV light and following the UV exposure the unexposed areas of the film are removed with a solvent such as amine-based strippers.

Liquid photoresist refers to a thin layer of a light-sensitive chemical solution applied directly onto a conductive pathway on the layer which acts as a protective mask during the etching process, allowing for precise patterning of the conductor to create desired circuit features using photolithography techniques. An exemplary liquid photoresist is produced by KemLab™ Inc. located in Woburn, Massachusetts. The liquid photoresist can be applied in several ways to include among others—spin coating, dip coating and low speed ultrasonic atomization coating all of which are well known in the industry.

Lastly, a solder mask (also known as a solder resist) is a protective layer used in the fabrication of layers to cover areas of the interconnect that should not be soldered. The primary function of the solder resist is to prevent solder from bridging between closely spaced traces, ensuring that the solder only adheres to the intended pads, connectors and/or leads. This is essential for creating reliable, high-quality electrical connections on a layer. A layer of liquid photo imageable solder resist is applied to the entire surface of the layer.

The interconnect is then exposed to ultraviolet (UV) light that defines the areas where the photo-sensitive resist should not be present (such as the superconducting traces). The areas exposed to the UV light harden. After exposure, the interconnect is washed with a developer solution that removes the areas of the resist that were not exposed to UV light, leaving the resist covering the areas that are not meant to have a superconducting material.

As illustrated at FIG. 2, after application of the masking image to the carrier metal a superconducting material is deposited upon the carrier metal as per step 208. In an exemplary context, a tin-lead alloy, commonly used in solder, is a superconductor when cooled to temperatures near absolute zero, meaning it exhibits limited to no electrical resistance at such extreme cold conditions; both tin and lead, the constituent metals, are individually known to be superconductors as well.

There are several methods for depositing superconducting material. One method for depositing a superconducting material upon a carrier metal includes electroplating. To enhance the bonding between the superconducting material and the substrate, the surface of the carrier metal is often activated. Activation involves processes such as plasma treatment, ion etching, micro etching, or applying a thin metallic adhesion layer. Electroplating involves using an electric current to reduce metal cations onto the carrier substrate. An electrolyte solution containing the superconducting material is used, and the substrate is submerged. A current is passed, causing the superconducting material to plate onto the metal substrate.

An alternative option for depositing superconducting material is using physical vapor deposition (PVD). With PVD the selected superconducting materials are evaporated in a vacuum chamber and then condense onto a substrate. This process is typically done in an argon or oxygen atmosphere (depending on the material), and the temperature is kept under control to prevent damage to the dielectric.

Another alternative method for depositing superconducting material is chemical vapor deposition (CVD). This deposition technique can be used because it involves the chemical reaction of gaseous precursor materials, which are decomposed to form a solid superconducting material that adheres to the dielectric substrate. This method is useful for creating high-quality thin films of superconducting materials. Another deposition method is known as pulsed laser deposition (PLD) which uses a high-energy laser to ablate material from a target and deposit it as a thin film onto the substrate.

The superconducting material is typically deposited in a very thin layer (in the range of micrometers or nanometers), ensuring that it has the right thickness to exhibit superconducting properties at the desired temperature. In some cases, additional processing steps such as annealing or oxygenation may be performed to achieve the desired crystalline structure and superconducting characteristics.

A next step in the interconnect fabrication process requires removing the masking image from the surface of the carrier metal thereby leaving a pattern of the superconducting material on top of the carrier metal a detailed at step 210. The masking image (or masking layer) on a carrier metal is typically a temporary layer applied to protect certain areas of the metal surface during various manufacturing processes, such as etching, plating, PVD, or soldering. After the desired process (such as etching or plating) is performed on the unprotected areas of the metal, the masking image is removed to reveal the final, processed surface of the metal.

A developer solution is typically used to dissolve the exposed or unexposed parts of the resist. For example, acetone, isopropyl alcohol (IPA), or specific photoresist removers can be used to clean up masking layers including photoresists. Acidic or alkaline solutions can also be used to remove organic-based masking materials. The removal of the masking image depends on the type of mask used and the process it was subjected to.

The next fabrication step requires laminating at least one layer of the carrier with superconducting material to a dielectric material 212. Laminating a layer of super-conducting material to a dielectric material serves several important purposes, especially in applications where the unique properties of superconductors are needed in conjunction with the electrical insulating properties of dielectrics. This combination is commonly used in quantum computing. Dielectric materials do not conduct electricity, which is important for preventing unwanted electrical interference and ensuring that signals are contained in the proper paths.

Superconducting materials conduct electricity with limited to no resistance when cooled below their critical temperature. However, they still need to be electrically isolated from certain regions or other components of a device to maintain signal integrity or to define controlled areas for current flow. By laminating the superconducting material to a dielectric, the dielectric serves as an electrical insulator between different regions or layers of the system, which is particularly important in high-frequency and high-power applications. Dielectric materials can also serve as an insulating layer that helps in maintaining the thermal gradient needed for the superconductor to remain below its critical temperature.

The dielectric material (such as ceramic, glass, or polymer films) must be cleaned to remove any dirt, oils, or contaminants. This ensures that the superconducting layer adheres properly and uniformly. The cleaning is typically done using solvents (such as isopropyl alcohol), plasma cleaning, or ultrasonic cleaning. The surface of the dielectric material may also be activated (through plasma treatment or chemical etching) to enhance the adhesion between the superconducting material and the dielectric. This can create a roughened surface or introduce functional groups that improve bonding.

The disclosed method next requires the etching of at least a portion of the carrier metal to expose the superconducting image laminated to the dielectric material 214. The etching of a portion of the carrier metal to expose the superconducting layer laminated to a dielectric material is an essential step in creating intricate patterns or electrical components on the composite material. Before etching, the laminated structure, consisting of a carrier metal superconducting material and a dielectric layer. The superconducting layer is often thin and is sandwiched between the metal and dielectric layers. The carrier metal is usually used for structural support during superconducting metallization or to facilitate electrical connections to the superconducting material.

The etching can be accomplished through either wet etching or dry etching. Wet etching involves the use of a chemical etchant that dissolves the exposed carrier metal. The chemical etchant is selected based on the type of metal used in the carrier layer. The laminated structure can be selectively masked, so the exposed metal is dissolved away, leaving behind the areas covered by the photoresist. Dry etching involves the use of a plasma (ionized gas) to remove the exposed metal. During this step, the carrier metal layer is etched away in the areas where the photoresist was removed or using laser ablation. The superconducting layer beneath those etched portions remains protected by the photoresist. If the interconnect consists of multiple layers the above series of steps are repeated, as illustrated at step 216. The next step is to laminate the layers together to form a multilayer flexible inter interconnect 218.

The disclosed method next requires at step 220 the creation of one or more via or component holes, to electrically connect the superconducting layers using either non-superconducting or superconducting electrically conductive materials. Depending on the design, vias can be classified as through-hole vias which go all the way through the interconnect, connecting all layers. The vias may also be blind vias which connect an outer layer to one or more inner layers but do not go all the way through the interconnect. Lastly, buried vias only connect inner layers and do not reach the outer layers of the interconnect.

Creating via holes in an electrical interconnect is an essential process in electronics manufacturing, particularly for creating connections between different layers of a multi-layer circuit interconnect or laminated material. The vias allow electrical signals to pass through layers of the material, enabling the creation of complex, high-density interconnects.

The holes may optionally be formed through either mechanical drilling or laser drilling. In mechanical drilling, a rotating drill bit is used to physically remove material and create holes. This method is typically used for larger via holes or when drilling through standard interconnect materials. Laser drilling uses high-powered lasers to burn through the material to create small, precise holes. This method is particularly useful for smaller vias and materials that are difficult to drill mechanically.

The size of the via holes is defined based on the design; however, the hole diameter is typically kept as small as possible while ensuring proper electrical and mechanical connectivity (e.g., typical via hole sizes range from 0.2 mm to 1 mm). For multi-layer interconnects, the drilling is performed through all layers of the interconnect (in the case of through-hole vias). For blind or buried vias, drilling is done selectively through only certain layers of the interconnect.

Once the vias are drilled and cleaned, they must be plated to make them electrically conductive. One way this can be done is by electroplating, where a thin layer of a conductor is deposited inside the via holes to create an electrical connection between the different layers. A pretreatment, well understood in the industry and required for all vias in circuit fabrication, is performed on the vias and component holes that includes the use of a chemical solution to promote adhesion by a conductor to the walls of the via holes. This pretreatment can take the form of either deposition of a thin layer of conductive material using electroless plating or deposition of a thin layer of conductive graphite. The substrate is then immersed in an electroplating bath, where an electrical current is used to deposit metal onto the inner walls of the via holes.

This process ensures that the vias become conductive and allow electrical signals to pass through the layers. The plating is carefully controlled to achieve the desired thickness of the conductor inside the vias. If the vias are too thin, the conductor may not adhere properly, and if they are too thick, it can cause problems with the vias' size and electrical characteristics.

The method next requires applying, as specified, to the exposed super-conducting and non-superconducting material, at least one of a coverlay, a solder mask or a surface finish to prevent oxidation as detailed at step 222. The, as specified, modifier pertains to the specification provided by the end user of the interconnect. Since user requirements can vary the implementation of this method can vary from one fabrication to the next; however, the application of a coverlay, solder mask, or surface finish to an exposed superconducting and non-superconducting material is an essential step to protect the material from environmental damage, particularly oxidation and corrosion, and to ensure long-term reliability. These coatings also help to improve solderability, durability, and the overall electrical performance of the component.

A coverlay is typically a flexible polymer layer that is used to protect specific regions of the flexible interconnects with flexible superconducting materials. The coverlay serves as a protective barrier against contaminants and oxidation while also providing mechanical support. The exposed areas of the superconducting or non-superconducting material are cleaned to remove any contaminants or oxidation. This can involve ultrasonic cleaning, plasma cleaning, or using chemical solvents. Next, a thin film of polyimide or another suitable polymer is laminated over the exposed regions. This material is flexible and can be applied with an adhesive lamination, where the material is pressed onto the circuit under heat and pressure.

If required, the coverlay may be selectively removed in specific areas to expose conductor pads or other conducting regions (such as for via holes or contact pads) using laser ablation or photo-patterning. The coverlay is usually applied to the entire surface except the areas where electrical contact is needed. As an alternative to the coverlay, a solder mask is a protective layer that is applied to the non-conductive areas of the circuit to prevent oxidation and to provide isolation between different conducting areas. A solder mask also prevents solder from bridging over to unintended regions during the soldering process.

As a second alternative to the coverlay, a liquid photo-imageable solder mask is applied to the surface of the interconnect. This material is typically a green epoxy-based compound. The liquid is applied via screen printing, roller coating, spray coating or slot die printing to cover the entire surface. The slot die is a tool with a narrow, elongated opening (or slot) through which the coating material is deposited onto the substrate.

The solder mask is then exposed to UV light to create a specific pattern that defines where the soldering pads and vias are exposed. The unexposed regions of the solder mask are then washed away, revealing the exposed pads for soldering. After the photoresist is developed, the solder mask is cured under heat (or sometimes UV light) to harden it into a durable protective coating. This step ensures that the solder mask adheres to the surface and prevents oxidation on the exposed conducting materials.

As a third alternative to the coverlay, or in addition to, a surface finish may optionally be applied to the exposed metallic surfaces to prevent oxidation and improve solderability. Common surface finishes include electroless nickel immersion gold (ENIG), electroless nickel electroless palladium immersion gold (ENEPIG), hot air soldering level (HASL), organic solderability preservative (OSP), hard gold, immersion or electrolytic silver, electroless palladium/immersion gold (EPIG), immersion or electrolytic tin or high phosphorous electroless nickel immersion gold.

When surface finishing with HASL, the interconnect is cleaned to remove any oxidation and contaminants from the surface. The interconnect is then dipped into a molten solder bath. After the solder is applied, the board is passed through hot air knives that remove the excess solder, leaving a thin, even solder coating on the exposed copper surfaces. The interconnect is cooled and then inspected to ensure the solder has formed a uniform, smooth surface that protects against oxidation.

When surface finishing with Electroless Nickel/Immersion Gold, the exposed metallic surfaces are cleaned and activated using a catalytic solution that prepares the surface for plating. The interconnect is then immersed an electroless nickel bath, where nickel is deposited onto the exposed conductor surfaces. After the nickel plating, the interconnect is immersed in a gold immersion bath. The gold plating provides additional protection against oxidation and enhances solderability. After the gold plating, the interconnect undergoes a final inspection to ensure uniform coverage and quality.

When surface finishing with Organic Solderability Preservative (OSP), the surface is cleaned to remove any oxidation or contamination and a thin layer of organic solderability preservative is applied to the exposed surfaces, which forms a protective coating. The Organic Solderability Preservative coating is then dried and cured, leaving a thin, transparent organic layer that prevents oxidation. Organic Solderability Preservative is environmentally friendly and does not affect the electrical or mechanical properties of the circuit significantly.

Lastly, when surface finishing with immersion tin, the conductor surface is cleaned and treated to promote adhesion. The interconnect is then immersed in an immersion tin bath, which deposits a thin layer of tin over the exposed conductor surfaces. After plating, the tin layer is inspected for thickness and uniformity to ensure proper protection against oxidation.

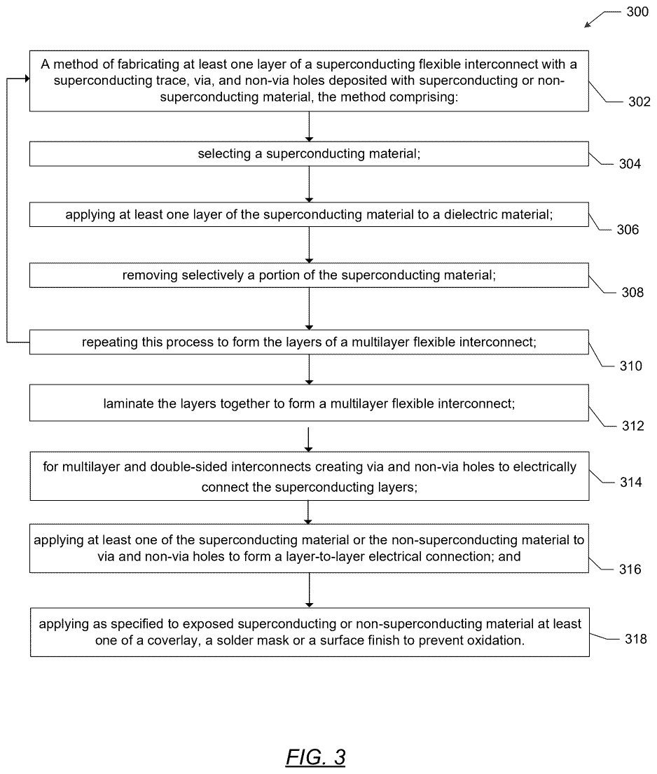

As illustrated at FIG. 3 and disclosed herein is an alternative method 300 of fabricating, in a subtractive manner, at least one layer of a superconducting flexible interconnect with a superconducting trace, via, and non-via holes deposited with superconducting or non-superconducting material 302. The first step in this process requires selecting a superconducting material 304. The process of selecting a superconducting material for a specific application involves considering a variety of factors. The first parameter to address is the critical temperature, which is the temperature at which a material becomes superconducting.

Most applications require a superconducting material with a critical temperature above the operating temperature of the application, e.g., quantum computing. Higher critical temperature materials are generally more desirable because they can operate at higher temperatures. For example, high-temperature superconductors, like yttrium barium copper oxide have a critical temperature above 77° K, allowing them to be cooled with liquid nitrogen, which is more affordable than liquid helium used for traditional low-temperature superconductors.

A second parameter to address is the critical magnetic field strength above which a superconducting material will lose its superconductivity. If the application involves high magnetic fields (e.g., in magnets), a material with a higher critical magnetic field strength is needed. The higher the field a material can withstand, the more useful it is in strong magnetic environments, such as in MRI machines or fusion reactors. The third parameter is critical current density which is defined as the maximum current the material can carry without losing its superconducting properties.

For applications like power cables or magnets, materials with high critical current density are needed to handle large currents without transitioning to a normal resistive state. A fourth parameter is the strength and flexibility of the superconductor. Many superconducting materials are brittle, which can make them difficult to use in certain applications, such as cables wires or flexible interconnects.

Some high temperature superconducting materials can be manufactured as flexible tapes, which may be more suited in some real-world applications. A fifth parameter is the thermal conductivity as the material should have sufficient thermal conductivity to prevent or dissipate heat buildup, especially when superconducting materials are operating near their critical temperature. A sixth parameter is cost and practicality because superconductors require cooling which adds cost. For instance, using liquid nitrogen for high temperature superconductors is cheaper than using liquid helium for low temperature superconductors.

Some applications operate at very low temperatures, and it is expensive to maintain those temperatures. Superconductors provide a cost savings because they will not add heat those systems, keeping the cooling costs low. Also, some materials are more expensive to manufacture, so cost considerations can affect the selection. A seventh parameter pertains to application specific requirements such as for quantum computing. Materials such as aluminum (for low-temperature superconducting qubits) or more exotic materials like niobium or indium are used in qubit design due to their low critical temperature and low noise properties.

An eighth parameter pertains to environmental and stability considerations. The material should be stable in the environment it will be exposed to, particularly in harsh conditions (e.g., exposure to oxygen, moisture, or radiation). Moreover, the long-term reliability must be assessed as some superconducting materials can degrade over time, so their long-term behavior must be evaluated for stability. Selecting the most appropriate superconducting material is a balance between performance (in terms of temperature, current, magnetic field, and other properties) and practical considerations like cost, fabrication ease, and application-specific requirements.

The next step is applying at least one layer of the superconducting material to a dielectric material 306. The dielectric layer acts as an electrical insulator between the superconducting material and other components or conductive layers. Common dielectrics include silicon dioxide (SiO₂), aluminum oxide (Al₂O₃), magnesium oxide (MgO), and thin-film polymers like polyimide. These materials need to be compatible with superconductors in terms of deposition methods and thermal expansion properties. Since superconducting materials are conductive and can carry current with limited to no resistance, a dielectric material ensures that there is no unwanted current leakage or short circuits between the superconducting interconnects and other elements, like ground planes, signal traces, or other superconducting lines.

In superconducting circuits, where high precision is crucial, the dielectric layer can help isolate different parts of the circuit, preventing undesired coupling between neighboring interconnects. In high-speed circuits, the capacitance between interconnects can influence the signal propagation speed. The dielectric properties of the layer help determine this capacitance, and thus, the behavior of the signal transmission. In superconducting digital or quantum circuits, controlling the capacitance is vital to maintain signal integrity and minimize signal loss or delay.

The dielectric layer provides dielectric strength, preventing electrical breakdown in the presence of high-voltage fields. When superconducting interconnects operate at high voltages, the dielectric material ensures that the system does not experience electrical breakdown (which could result in damage to the superconducting interconnect or other components). In certain applications, the dielectric layer can also play a role in thermal isolation between the superconducting material and other layers or substrates.

A dielectric layer can also reduce heat transfer to and from the interconnects, potentially minimizing thermal effects that could disrupt superconductivity. The dielectric layer can provide mechanical support and structural integrity to the superconducting interconnects. Superconducting interconnects are often thin and can be quite fragile, especially when made of brittle materials like ceramic-based high temperature superconductors. The dielectric layer can provide the necessary mechanical strength to prevent cracking or bending, ensuring that the superconducting wires maintain their integrity over time.

As discussed above, the dielectric material can be applied using several deposition techniques, depending on the specific material, the required thickness, and the precision needed. These techniques include lamination, chemical vapor deposition, sputtering, atomic layer deposition, thermal evaporation and spin coating.

The next step in the alternative method of fabricating in a subtractive manner at least one layer of a superconducting flexible interconnect with a superconducting trace, via, and non-via holes deposited with superconducting or non-superconducting material requires removing selectively a portion of the superconducting material 308. In the fabrication of a superconducting interconnect, selectively removing a portion of the superconducting material from a dielectric material is a critical step in defining the desired pattern and ensuring proper functionality. This process is typically performed using photolithography and etching techniques, which allow for precise control over the areas to be removed and the areas to be preserved.

The substrate thin film of superconducting material is first thoroughly cleaned to remove contaminants such as organic residues, dust, and oxides. Common cleaning methods include rinsing with solvents like acetone, isopropyl alcohol, and deionized water, followed by drying with nitrogen or air. In some cases, a surface treatment is performed to ensure good adhesion between the superconducting layer and the dielectric. For example, the surface might be treated with plasma to remove native oxide layers or to promote adhesion.

A thin layer of photoresist, which is a light-sensitive polymer, is applied to the superconducting surface. The thickness of the photoresist is adjusted based on the required pattern size and the etching process. Plasma etching is commonly, but not exclusively used, to etch superconducting. In this process, a gas is ionized in a vacuum chamber, and the ions react with the superconducting material to remove it from the surface. The photoresist pattern serves as a mask, protecting the areas of the superconducting material that should remain intact. In some cases, wet chemical etching is used, where the substrate is immersed in an etching solution that chemically reacts with the superconducting material.

After the superconducting material has been etched and the desired pattern has been achieved, the remaining photoresist is removed in a process known as resist stripping. This step involves immersing the substrate in a solvent or using an oxygen plasma to remove the remaining photoresist. The use of oxygen plasma is particularly effective for burning off organic photoresist residues without damaging the underlying layers. After resist removal, the interconnect is thoroughly cleaned to ensure there are no residues left from the etching or photoresist processes. This can include rinsing with solvents, followed by deionized water rinsing and drying.

The above steps of applying at least one layer of the superconducting material to a dielectric material and then removing selectively a portion of the superconducting material are repeated, as detailed at step 310, as required to form a multilayer flexible interconnect. Once those steps, if selected for repetition are completed, the layers can be laminated to form a multilayer flexible interconnect 312. Then the via and non-via holes to electrically connect the superconducting layers are created in the multilayer and double-sided interconnects.

The next step in the disclosed method 300 is creating via and non-via holes in layer-to-layer connections within superconducting interconnects is an essential step in the fabrication of multi-layer superconducting interconnects 314. The vias enable electrical connections between different layers of the circuit, allowing signals or power to be routed between different parts of the device. As previously detailed, there are two main types of holes that are created in the dielectric layer for interconnects. These include via holes and non-via holes with via holes being vertical connections between different layers of the superconducting circuit.

The next step in the disclosed method requires applying at least one of the superconducting material or the non-superconducting material to via and non-via holes to form a layer-to-layer electrical connection 316. The electrical connection in via holes are typically made through an electroless or electrolytic plating process. They may be filled with a conductive material to create electrical paths between layers and may be created by etching through the dielectric layer to the superconducting layer and filling with metal, if needed. Non-via holes are openings or patterns used for routing or other structural purposes.

The final step in the disclosed method is the applying to exposed superconducting or non-superconducting material of at least one of a coverlay, a solder mask or a surface finish to prevent oxidation 318. Since user requirements can vary the implementation of this method can vary from one fabrication to the next; however, the application of a coverlay, solder mask, or surface finish to an exposed superconducting and non-superconducting material is an essential step to protect the material from environmental damage, particularly oxidation and corrosion, and to ensure long-term reliability. These application steps are as previously disclosed above.

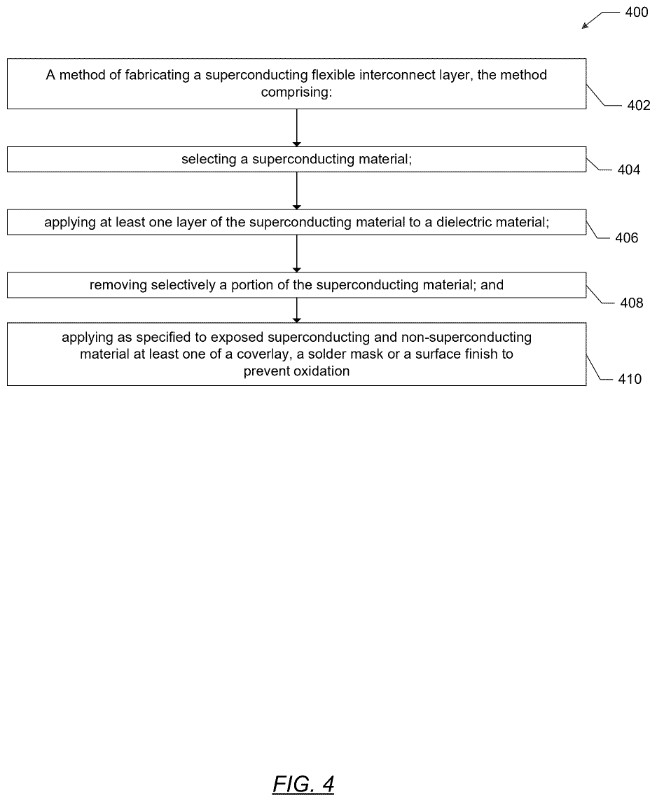

As illustrated at FIG. 4 is a third method 400 for fabricating a super-conducting flexible interconnect layer with a superconducting trace described as the superconducting foil single layer 402. This third method of fabrication is consistent with the subtractive second method 300 detailed above except that it does not include the step of repeating the previously practiced steps to form a multilayer flexible interconnect and vias are not applicable.

The first step in this process requires selecting a superconducting material as detailed at step 404. The process of selecting a superconducting material for a specific application involves considering a variety of factors that have been discussed in detail above and include the superconducting material's critical temperature, which is the temperature at which a material becomes super-conducting, critical magnetic field strength above which a superconducting material will lose its superconductivity, critical current density which is defined as the maximum current the material can carry without losing its superconducting properties, strength and flexibility of the superconductor, thermal conductivity, cost and practicality because superconductors require cooling which may add cost.

Next the method requires the applying of at least one layer of the superconducting material to a dielectric material 406. The dielectric layer acts as an electrical insulator between the superconducting material and other components or conductive layers. Common dielectrics, as discussed above, include silicon dioxide (SiO₂), aluminum oxide (Al₂O₃), magnesium oxide (MgO), and thin-film polymers like polyimide. These materials need to be compatible with superconductors in terms of deposition methods and thermal expansion properties. In superconducting circuits, where high precision is crucial, the dielectric layer can help isolate different parts of the circuit, preventing undesired coupling between neighboring interconnects.

The next step in this method of fabricating at least one layer of a superconducting flexible interconnect with a superconducting trace requires removing selectively a portion of the superconducting material as detailed at step 408. In the fabrication of a superconducting interconnect, selectively removing a portion of the superconducting material from a dielectric material is a critical step in defining the desired pattern and ensuring proper functionality. This process is typically performed using photolithography and etching techniques as previously detailed above.

The final step in the disclosed method is the applying as specified to exposed superconducting or non-superconducting material at least one of a coverlay, a solder mask or a surface finish to prevent oxidation as detailed at step 410. The as specified, aspect pertains to the specification provided by the end user of the interconnect. Since user requirements can vary the implementation of this method can vary from one fabrication to the next; however, the application of a coverlay, solder mask, or surface finish to an exposed superconducting and non-superconducting material is an essential step to protect the material from environmental damage, particularly oxidation and corrosion, and to ensure long-term reliability.

The fourth disclosed method 500 pertains to the fabrication of a single layer of superconducting flexible interconnect. The first step is directed to selecting a carrier foil of a non-superconducting and electrically conductive material 504. The second step is the applying a masking material to the electrically conductive material 506. Next, the method requires the step of printing of an image upon the masking material 508, followed by the step of depositing of a superconducting material upon the carrier foil 510.

Following the depositing step, the method requires the step of removing the masking material from the coated surface of the carrier foil thereby leaving the superconducting material patterned on top of the carrier foil 512. Following the removal of the masking material the method requires the step of laminating a layer of the superconducting interconnect to a dielectric material 514. Next the method requires the step of removing at least a portion of the carrier foil to leave a superconducting image laminated to a dielectric material 516. The final step is applying to the exposed superconducting or non-superconducting material at least one of a coverlay, a solder mask or a surface finish to prevent oxidation 518.

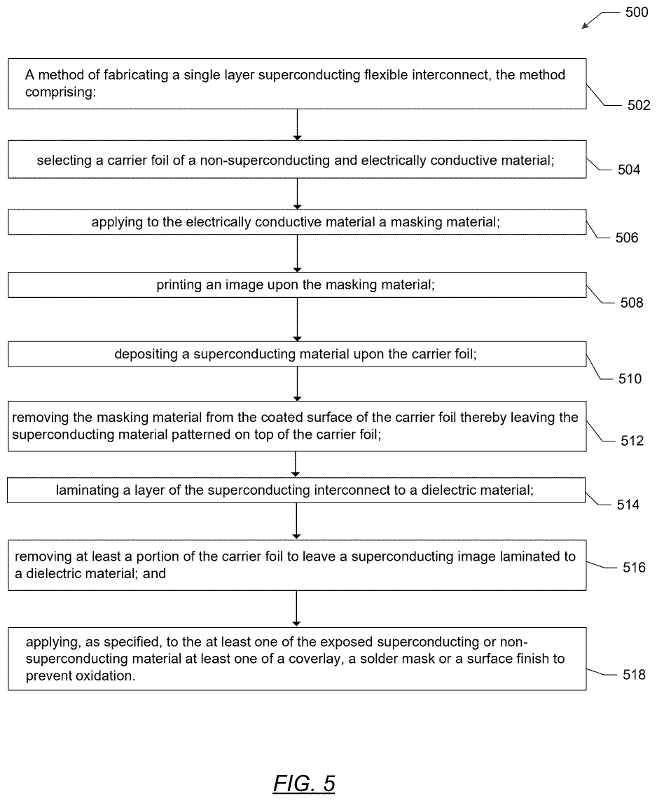

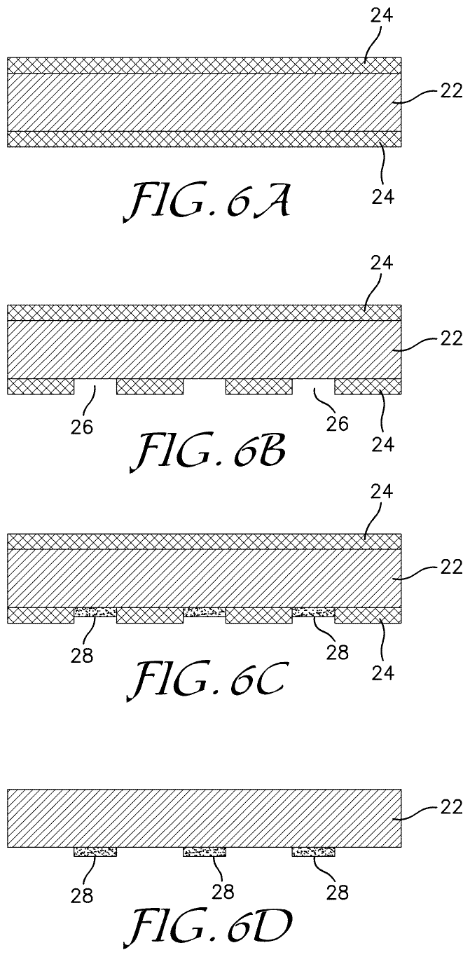

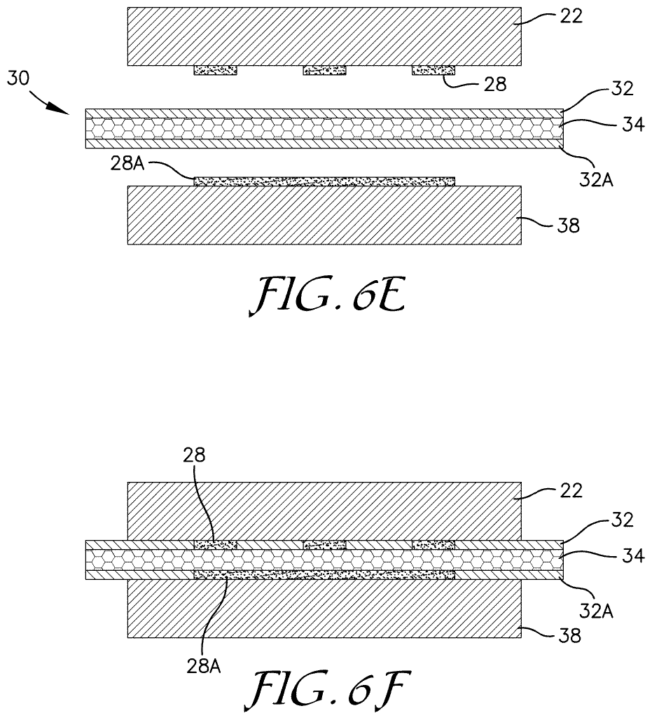

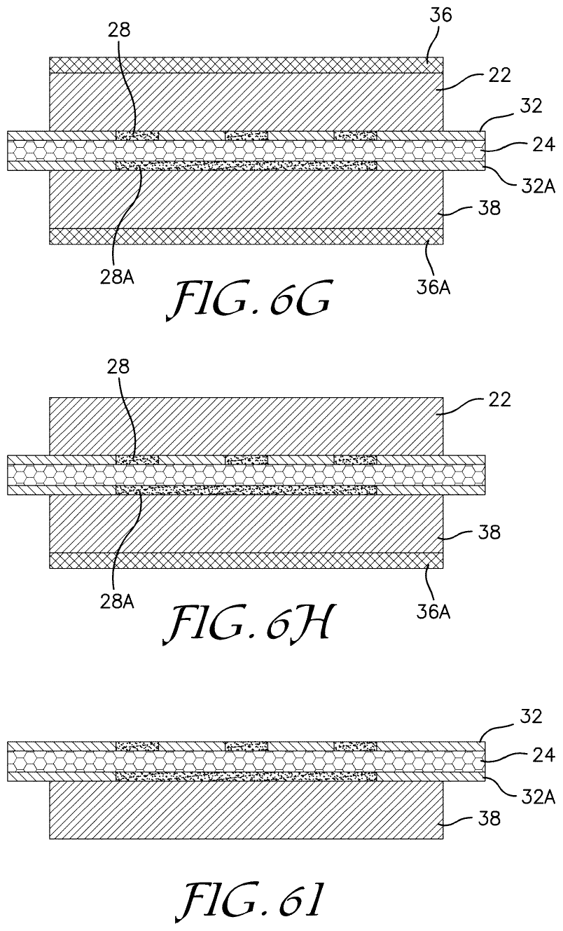

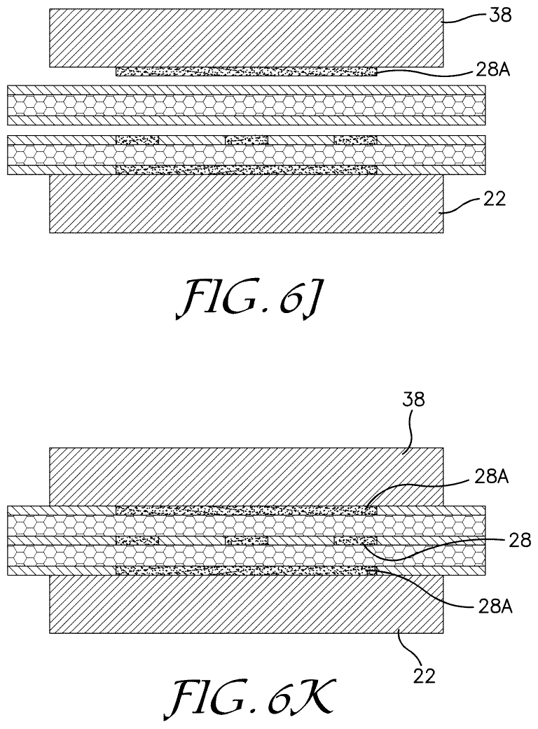

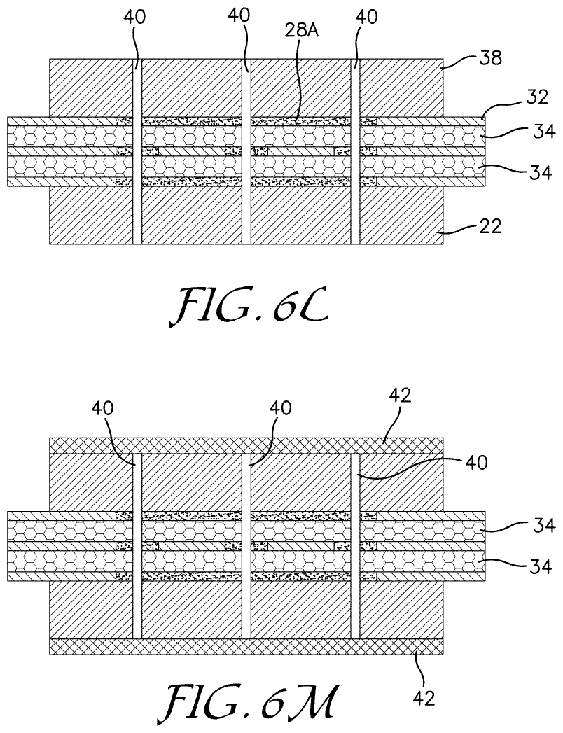

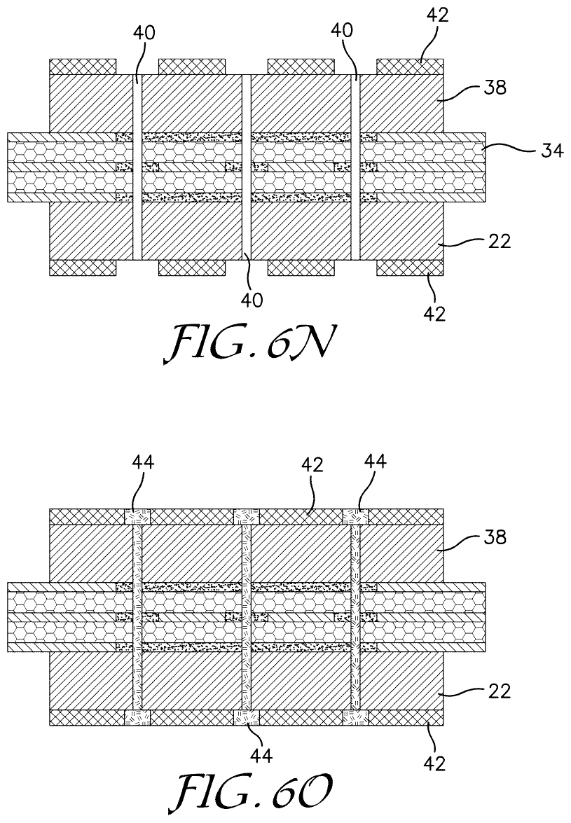

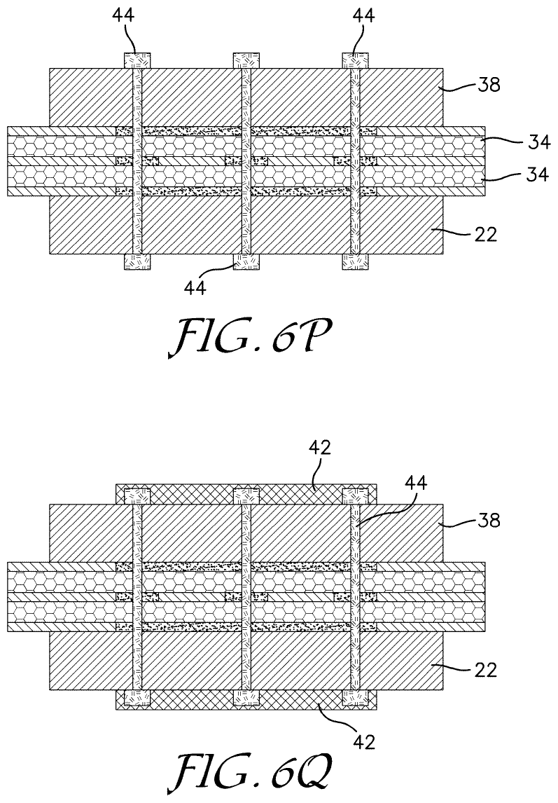

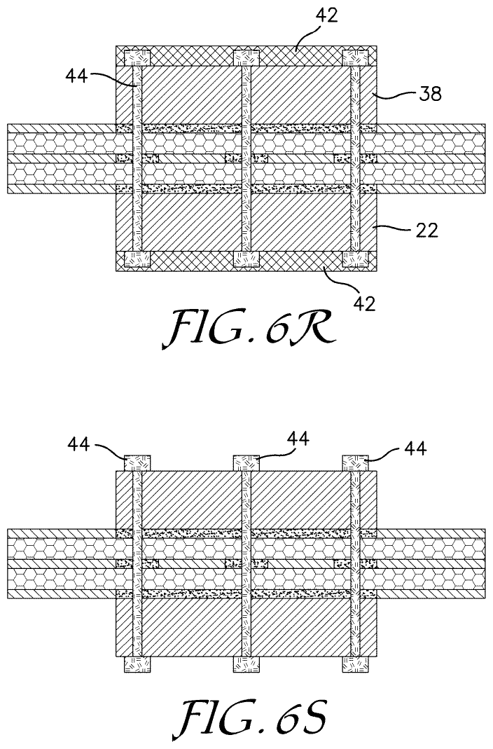

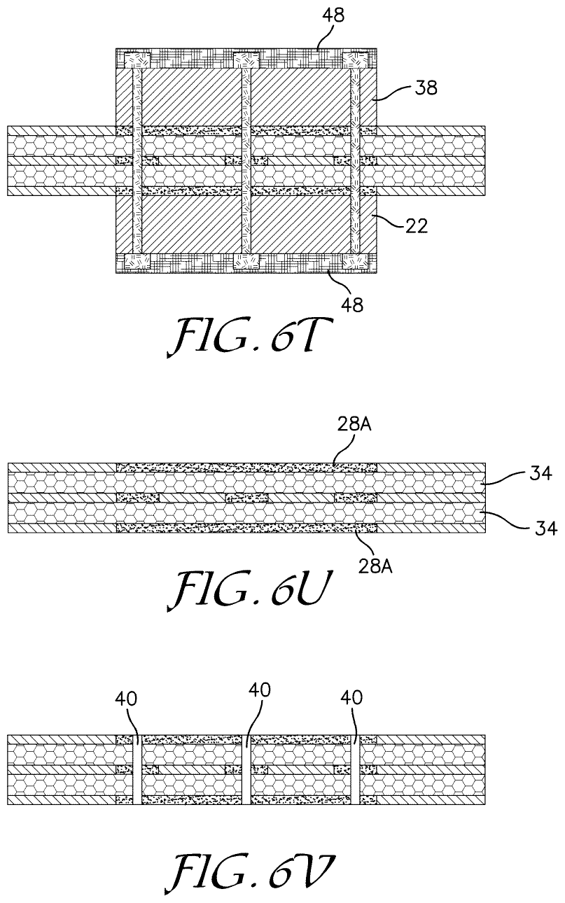

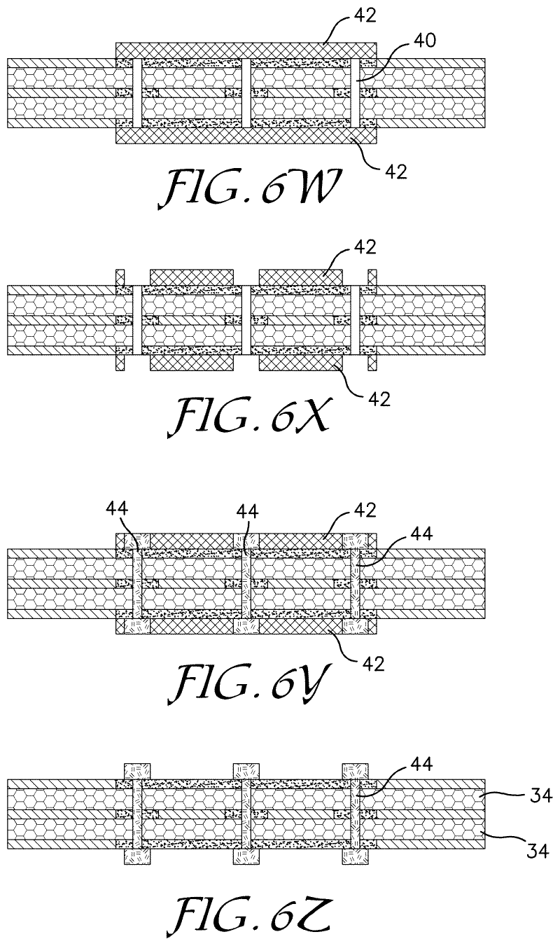

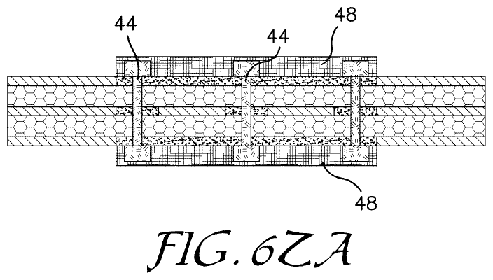

FIGS. 6A-ZA all illustrate a cross-sectional view (from side to side of the interconnect) of the physical configuration of a flexible superconducting interconnect 10 during various stages of the fabrication process which is essentially consistent with the additive process as illustrated at FIG. 2. FIG. 6A illustrates a view of a carrier foil 22 with a photoresist masking 24 applied to the carrier foil. FIG. 6B illustrates the carrier foil 22 with unwanted photoresist masking removed as shown by the open spaces 26.

This removal process requires the carrier foil and photoresist masking 24 to go through an imaging process which creates the resist pattern that protects the carrier foil from the etchant. The resist pattern precisely defines the circuit traces and is a critical step. A development process serves to remove the unwanted photoresist. FIG. 6C illustrates the carrier foil 22 with superconducting material 28 added. FIG. 6D illustrates the carrier foil 22 stripped of photoresist leaving only the superconducting traces 28 on the carrier foil 22.

FIG. 6E illustrates a lamination layer 30 disposed between the spaced apart carrier foil 22 with superconducting traces 28, 28A. The lamination layer 30 includes two adhesive layers 32, 32A with a polyimide (dielectric) 34 disposed between the layers 32, 32A. FIG. 6F illustrates the lamination layer 30 disposed between and adhered to the carrier 22 with superconducting traces 28, 28A. FIG. 6G illustrates the application of masking material 36 to the carrier foil 22 with hardened masking material 36A on one side following an imaging process.

FIG. 6H illustrates the development of masking material, leaving masking material 36A on one side only. After exposure, the interconnect is washed with a developer solution that removes the areas of the masking material 36 that were not exposed to UV light, leaving the masking material covering the areas that are not meant to have a superconducting material. FIG. 6I illustrates the carrier foil 22 etched (removed) on one side and removing the masking material 36A. FIG. 6J illustrates the repeating of the above steps to create a top layer 38 and the lamination of the top layer 38 to the remainder of the interconnect 10. FIG. 6K illustrates the laminated superconductor traces 28, 28A disposed between top and bottom carrier foil caps 22, 38.

The method of fabrication of the interconnect 10 can optionally diverge at the next step and a first path for completing the interconnect starts at FIG. 6L which illustrates the clean barrel of the drilled or lasered via holes. FIG. 6M illustrates the masking material 42 applied and imaged. Next, FIG. 6N illustrates the masking material 42 being developed to remove unwanted masking. FIG. 6O illustrates the application of either superconducting or non-superconducting material 44 to the via holes 40.

FIG. 6P illustrates the masking material 42 removed while FIG. 6Q illustrates the application of masking material 42 that is imaged, and along with the removal/development of a portion of the masking. FIG. 6R illustrates the etching of a portion of the carrier 22, 38 while FIG. 6S illustrates the removal of the masking material 42 and FIG. 6T illustrates the application of a coverlay, soldermask and/or a surface finish 48 to the circuit.

An alternative path to the fabrication of the flexible superconducting interconnect 10 after the step shown at FIG. 6K is illustrated starting at FIG. 6U which details the etching and removal of either all or a portion of the carrier 22, 38. FIG. 6V illustrates the clean barrel of the drilled or lasered via holes 40 while FIGS. 6W and 6X illustrate respectively the applied masking material 42 that is imaged as previously described and the development of the masking material 42 by selectively exposing the carrier and/or the superconducting layer 22. FIGS. 6Y, 6Z and 6ZA illustrate respectively the application of either superconductive or non-superconductive material 44 to the via holes 40, then the removal of masking material 42 and finally the application of coverlay, soldermask and or surface finish 48 to complete the fabrication of the flexible superconducting interconnect 10.

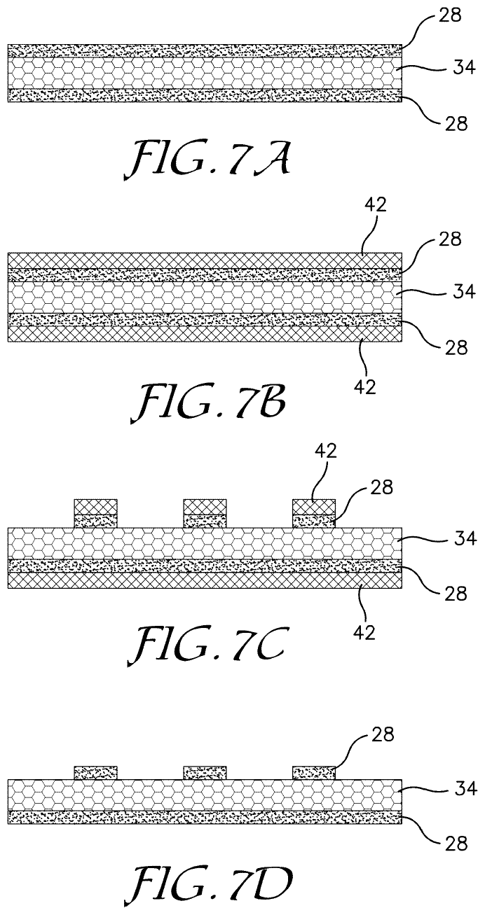

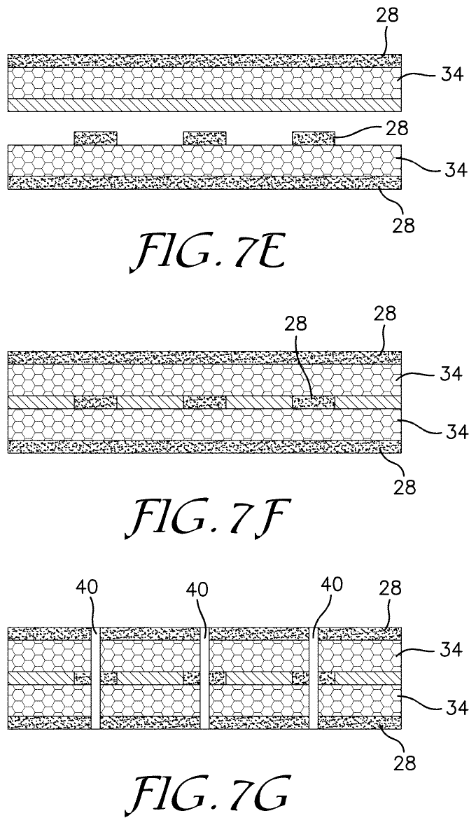

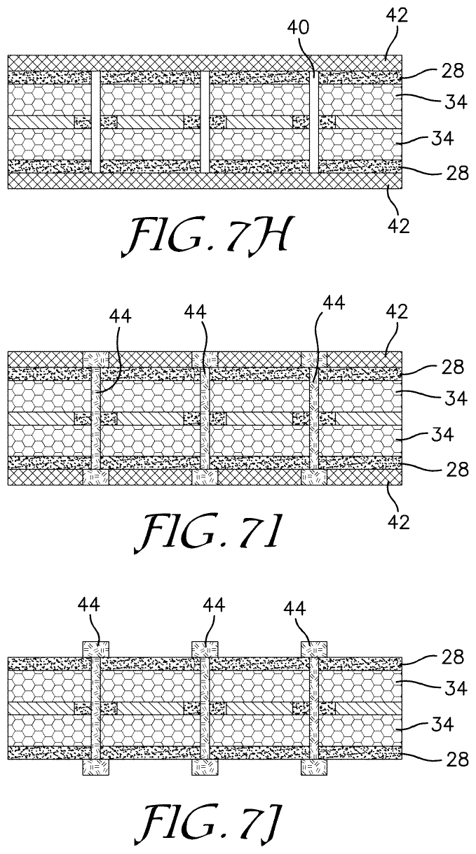

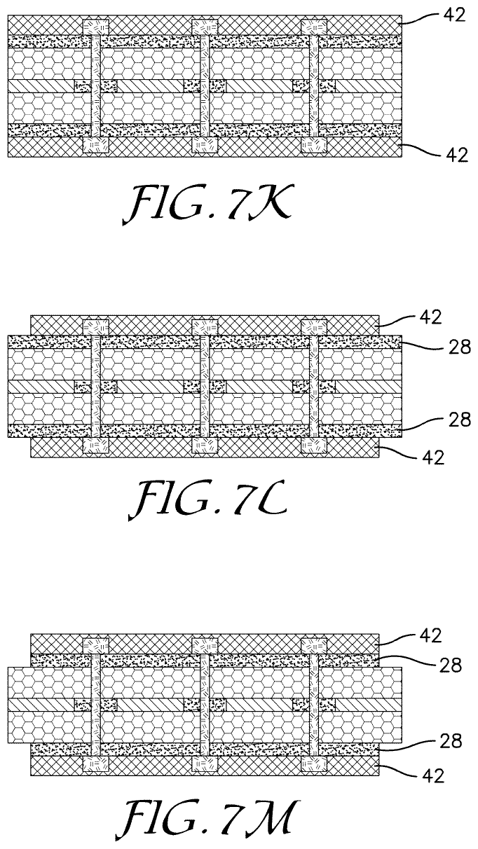

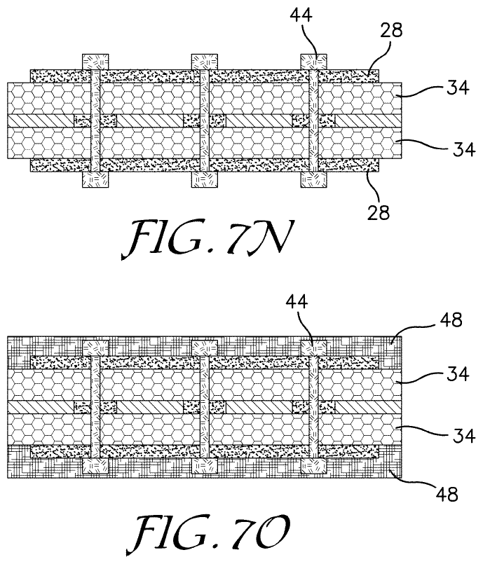

To add additional context to the subtractive fabrication process as previously set forth at FIG. 3, a series of figures are provided that, as with FIGS. 6A-6ZA, illustrate a side-to-side cross-sectional view of the flexible superconducting interconnect 10. FIG. 7A illustrates the application of a superconducting material 28 to the dielectric 34 done optionally through any of lamination, plating or a sputtering process. The application of the superconducting material may be done or one or both sides of the dielectric 34. FIG. 7B illustrates the application of the masking material 42 while FIG. 7C illustrates the imaging process followed by the development process which has removed the unwanted masking material 42.

Next, FIG. 7D illustrates only the superconducting pattern on the carrier after the removal of the masking image. For multilayer superconducting interconnects 10, as illustrated at FIG. 7E, at least one layer of the superconducting material 28 is laminated to the dielectric 34 while FIG. 7F illustrates the laminated interconnect with FIG. 7G illustrates the via holes 40 that have been formed by drilling or lasering. After the formation of the vias 40, masking material 42 is applied, and the interconnect is imaged as illustrated at FIG. 7H. Next, as illustrated by FIG. 7I, superconducting or non-superconducting material 44 is applied to the via holes 40 and then the masking material 42 is removed as illustrated at FIG. 7J.

After removal of the previously applied masking material another round of masking material 42 is applied as illustrated at FIG. 7K and the imaging process is performed upon the applied masking material 42. Next, as illustrated at FIG. 7L, the masking material 42 is developed, as previously detailed, and the masking material 42 in unwanted areas is removed exposing the superconducting material 28. Once that fabrication step is completed, selective portions of the superconducting material 28 is removed as illustrated at FIG. 7M. The two remaining steps include once again removing the masking material 42 as illustrated at FIG. 7N and finally as illustrated at FIG. 7O, the applying of a coverlay, soldermask, and/or a surface finish 48 to the flexible interconnect thereby completing the alternative path to fabrication of the flexible superconducting interconnect 10.

Each of the fabrication methods disclosed herein requires the step of applying to the exposed super-conducting and non-superconducting material one or more of a coverlay, a solder mask or a surface finish to prevent oxidation. The step of applying also includes printing, and developing one or more of the coverlay, the solder mask or the surface finish and the fabrication method also contemplates developing the coverlay, soldermask and surface finishing by screen printing or slot die coating and curing. The solder mask includes laminating a dielectric material.

The disclosed fabrication methods also all include the step of applying a masking image to a carrier metal that includes coating the carrier metal with at least one of a dry film, a liquid photoresist or a solder mask and the step of applying the masking image to the carrier metal includes printing the masking image using photolithography.

All the disclosed fabrication methods include printing the coverlay, solder mask or surface finish as development of the solder mask and the development of the solder mask includes screen printing and curing. While the step of depositing a superconducting material upon the carrier metal comprises one or more of plating, physical vapor deposition, or chemical vapor deposition.

Also contemplated by this disclosure for all fabrication methods is that the step of creating a via or a component hole to electrically connect superconducting layers includes at least one of mechanically or laser drilling the flexible interconnect and the step of creating a via or a component hole includes one or more of plating, hole filling, physical vapor deposition or chemical vapor deposition.

Surface finishes for each of the disclosed methods includes one or more of electroless nickel immersion gold (ENIG), electroless nickel electroless palladium immersion gold (ENEPIG), hot air soldering level (HASL), organic solderability preservative (OSP), hard gold, immersion or electrolytic silver, electroless palladium/immersion gold (EPIG), immersion or electrolytic tin or high phosphorous electroless nickel and immersion gold. Lastly, all methods disclosed herein that reference the step of removing selectively a portion of the superconducting material are accomplished by etching or laser ablation.

In view of the many possible embodiments to which the principles of the disclosed invention may be applied, it should be recognized that the illustrated embodiments are only examples of the disclosure and should not be taken as limiting the scope of the invention. Rather, the scope of the invention is defined by the following claims. We therefore claim as our invention all that comes within the scope of these claims.

The disclosure presented herein is believed to encompass at least one distinct invention with independent utility. While the at least one invention has been disclosed in exemplary forms, the specific embodiments thereof as described and illustrated herein are not to be considered in a limiting sense, as numerous variations are possible. Equivalent changes, modifications, and variations of the variety of embodiments, materials, compositions, and methods may be made within the scope of the present disclosure, achieving substantially similar results. The subject matter of the at least one invention includes all novel and non-obvious combinations and sub-combinations of the various elements, features, functions and/or properties disclosed herein and their equivalents.

Benefits, other advantages, and solutions to problems have been described herein regarding specific embodiments. However, the benefits, advantages, solutions to problems, and any element or combination of elements that may cause any benefits, advantage, or solution to occur or become more pronounced are not to be considered as critical, required, or essential features or elements of any or all the claims of at least one invention.

Many changes and modifications within the scope of the instant disclosure may be made without departing from the spirit thereof, and the one or more inventions described herein include all such modifications. Corresponding structures, materials, acts, and equivalents of all elements in the claims are intended to include any structure, material, or acts for performing the functions in combination with other claim elements as specifically recited. The scope of the one or more inventions should be determined by the appended claims and their legal equivalents, rather than by the examples set forth herein.

Benefits, other advantages, and solutions to problems have been described herein regarding specific embodiments. Furthermore, the connecting lines, if any, shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the inventions.

The scope of the inventions is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C. Different cross-hatching may be used throughout the figures to denote different parts but not necessarily to denote the same or different materials.

In the detailed description herein, references to “one embodiment,” “an embodiment,” “an example embodiment,” etc., indicate that the embodiment described may include a feature, structure, or characteristic, but every embodiment may not necessarily include the feature, structure, or characteristic. Moreover, such phrases are not necessarily referring to the same embodiment. Further, when a feature, structure, or characteristic is described relating to an embodiment, it is submitted that it is within the knowledge of one skilled in the art to affect such feature, structure, or characteristic relating to other embodiments whether explicitly described or not. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. § 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The method steps described in this disclosure are not intended to be limited to the specific order presented in the claims. While the steps may be described sequentially for clarity, it is understood that the order of the steps may be altered or rearranged without departing from the scope of the invention. The method is intended to be flexible in its application, allowing for variations in the sequence of steps based on specific implementation requirements, processing capabilities, or other considerations. As such, the invention encompasses any and all orders of execution for the steps, provided the desired result or function of the invention is achieved.

The invention has been described above with reference to one or more preferred embodiments, it will be appreciated that various changes or modifications may be made without departing from the scope of the invention as defined in the appended claims.

We claim:

1. A superconducting flexible interconnect comprising:
a superconducting material deposited on at least one of a metal layer, a ceramic layer, or an engineered polymer, wherein
the flexible superconducting interconnect comprises at least one of a single layer or a multi-layer configuration, the multi-layer configuration comprising at least one via with an electrically conductive material that is at least one of superconducting or non-superconducting.

2. The superconducting flexible interconnect of claim 1, wherein a surface of the flexible interconnect comprises a surface finish.

3. The superconducting flexible interconnect of claim 2, wherein the surface finish comprises at least one of electroless nickel immersion gold (ENIG), electroless nickel electroless palladium immersion gold (ENEPIG), hot air soldering level (HASL), organic solderability preservative (OSP), hard gold, immersion or electrolytic silver, electroless palladium/immersion gold (EPIG), immersion or electrolytic tin or high phosphorous electroless nickel immersion gold.

4. The superconducting flexible interconnect of claim 1, wherein the composition of the flexible interconnect comprises a stiffener.

5. The superconducting flexible interconnect of claim 1, wherein the flexible interconnect comprises at least one of an assembled or an embedded component.

6. A method of fabricating at least one layer of a superconducting flexible interconnect with a superconducting trace, a via and a non-via hole deposited with at least one of a non-superconducting material or a superconducting material, the method comprising:
selecting an electrically conductive carrier metal;
applying a masking image to the carrier metal;
depositing a superconducting material upon the carrier metal;
removing the masking image from the surface of the carrier metal thereby leaving a pattern of the superconducting material on top of the carrier metal;
laminating at least one layer of the superconducting material to a dielectric material;
etching at least a portion of the carrier metal to expose the superconducting image laminated to the dielectric material;
repeating the above steps to form a multilayer flexible interconnect;
laminating the layers together to form a multilayer flexible interconnect;
creating at least one of a via or a component hole to electrically connect the superconducting layers using either non-superconducting or superconducting electrically conductive materials; and
applying as specified to the exposed superconducting and non-superconducting material, at least one of a coverlay, a solder mask or a surface finish to prevent oxidation.

7. The method of claim 6, wherein the step of applying as specified to the exposed superconducting and non-superconducting material at least one of the coverlay, the solder mask or the surface finish to prevent oxidation comprises coating the carrier metal with at least one of the coverlay, the solder mask or the surface finish.

8. The method of claim 7, wherein the step of applying as specified to the exposed superconducting and non-superconducting material the at least one of the solder mask, the coverlay or the surface finish further comprises printing the at least one of the coverlay, the solder mask or the surface finish.

9. The method of claim 8, wherein the step of printing the at least one of the coverlay, the solder mask or the surface finish further comprises developing the at least one of the coverlay, the solder mask or the surface finish.

10. The method of claim 9, wherein the step of developing the at least one of the coverlay, the solder mask or the surface finish comprises at least one of screen printing or slot die coating and curing.

11. The method of claim 8, wherein the step of applying as specified to the exposed superconducting and non-superconducting material the solder mask, comprises laminating a dielectric material.

12. The method of claim 6, wherein the step of applying a masking image to the carrier metal comprises coating the carrier metal with at least one of a dry film, a liquid photoresist or a solder mask.

13. The method of claim 12, wherein the step of applying a masking image to the carrier metal further comprises printing the masking image using photolithography.

14. The method of claim 9, wherein the step of printing the at least one of the coverlay, the solder mask or the surface finish further comprises developing the mask.

15. The method of claim 9, wherein the step of developing the at least one of the coverlay, the solder mask or the surface finish comprises screen printing and curing.

16. The method of claim 6, wherein the step of depositing a superconducting material upon a carrier metal comprises at least one of plating, physical vapor deposition or chemical vapor deposition.

17. The method of claim 6, wherein the step of creating at least one of a via or a component hole to electrically connect superconducting layers comprises at least one of mechanically or laser drilling the flexible interconnect.

18. The method of claim 6, wherein the step of creating at least one of a via or a component hole comprises at least one of plating, hole filling, physical vapor deposition or chemical vapor deposition.

19. The method of claim 6, wherein the surface finish comprises at least one of electroless nickel immersion gold (ENIG), electroless nickel electroless palladium immersion gold (ENEPIG), hot air soldering level (HASL), organic solderability preservative (OSP), hard gold, immersion or electrolytic silver, electroless palladium/immersion gold (EPIG), immersion or electrolytic tin or high phosphorous electroless nickel immersion gold.

20. A method of fabricating at least one layer of a superconducting flexible interconnect with a superconducting trace, via, and non-via holes deposited with superconducting or non-superconducting material, the method comprising:
selecting a superconducting material;
applying at least one layer of the superconducting material to a dielectric material;
removing selectively a portion of the superconducting material;
repeating this process to form the individual layers of a multilayer flexible interconnect;
laminating together the layers to form a multilayer flexible interconnect;
for multilayer and double-sided interconnects creating via and non-via holes to electrically connect the superconducting layers;
applying at least one of the superconducting material or the non-superconducting material to via and non-via holes to form a layer-to-layer electrical connection; and
applying to exposed superconducting or non-superconducting material at least one of a coverlay, a solder mask or a surface finish to prevent oxidation.

21. The method of claim 20, wherein the step of applying as specified to the exposed superconducting and non-superconducting material at least one of the coverlay, the solder mask or the surface finish to prevent oxidation comprises coating the carrier metal with at least one of the coverlay, the solder mask or the surface finish.

22. A method of fabricating a single layer superconducting flexible interconnect, the method comprising:
selecting a carrier foil of a non-superconducting and electrically conductive material;
applying to the electrically conductive material a masking material;
printing an image upon the masking material;
depositing a superconducting material upon the carrier foil;
removing the masking material from the coated surface of the carrier foil thereby leaving the superconducting material patterned on top of the carrier foil;
laminating a layer of the superconducting interconnect to a dielectric material;
removing at least a portion of the carrier foil to leave a superconducting image laminated to a dielectric material; and
applying, as specified, to the at least one of the exposed superconducting or non-superconducting material at least one of a coverlay, a solder mask or a surface finish to prevent oxidation.

23. The method of claim 22, wherein the step of applying as specified to the exposed superconducting and non-superconducting material at least one of the coverlay, the solder mask or the surface finish to prevent oxidation comprises coating the carrier metal with at least one of the coverlay, the solder mask or the surface finish.

24. The method of claim 23, wherein the step of applying as specified to the exposed superconducting and non-superconducting material the at least one of the solder mask, the coverlay or the surface finish further comprises printing the at least one of the coverlay, the solder mask or the surface finish.

25. The method of claim 24, wherein the step of printing the at least one of the coverlay, the solder mask or the surface finish further comprises developing the at least one of the coverlay, the solder mask or the surface finish.

26. The method of claim 25, wherein the step of developing the at least one of the coverlay, the solder mask or the surface finish comprises at least one of screen printing or slot die coating and curing.

27. The method of claim 22, wherein the step of applying as specified to the exposed superconducting and non-superconducting material the solder mask, comprises laminating a dielectric material.

28. The method of claim 22, wherein the step of applying a masking image to the carrier metal comprises coating the carrier metal with at least one of a dry film, a liquid photoresist or a solder mask.

29. The method of claim 28, wherein the step of applying the masking image to the carrier metal further comprises printing the masking image using photolithography.
